(19) United States
(12) Patent Application Publication
(10) Pub. No.: US 2026/0204890 A1
(43) Pub. Date: Jul. 16, 2026

(54) CIRCUIT BREAKER

(71) Applicant: FUJI ELECTRIC FA COMPONENTS & SYSTEMS CO., LTD., Saitama (JP)

(72) Inventor: Takashi Hashimoto, Tochigi (JP)

(21) Appl. No.: 19/402,042

(22) Filed: Nov. 26, 2025

(30) Foreign Application Priority Data
Jan. 15, 2025 (JP) 2025-005528

(51) Int. Cl. H02H 3/08; H02H 3/033

(52) U.S. Cl. CPC H02H 3/08; H02H 3/033

(57) ABSTRACT

A circuit breaker includes a main circuit, a mechanical switch that switches the main circuit between a conduction state and an interruption state, a semiconductor device that is coupled in series on a downstream side of the mechanical switch and switches the main circuit between the conduction state and the interruption state, a sensor that outputs a signal according to a current flowing through the main circuit, a control circuit that detects the current flowing through the main circuit based on an output signal of the sensor, and a power supply circuit that is coupled to an upstream side of the mechanical switch via a first switch and supplies power to the control circuit when the first switch is turned on.

### CROSS-REFERENCE TO RELATED APPLICATIONS

This application is based upon and claims priority to Japanese Patent Application No. 2025-005528, filed on January 15, 2025, the entire contents of which are incorporated herein by reference.

### FIELD

Certain aspects of the embodiments discussed herein are related to circuit breakers.

### BACKGROUND

A known DC circuit breaker includes an input terminal connected to a power supply, an output terminal connected to a load, a semiconductor switch connected between the input terminal and the output terminal, a switch connected between the input terminal and the semiconductor switch, and a controller that controls the semiconductor switch and the switch. In this DC circuit breaker, upon receiving a conduction instruction via a user operation or an automatic instruction device, the controller closes (turns on) the switch having a mechanical contact before turning on the semiconductor switch (refer to Japanese Laid-Open Patent Publication No. 2022-181346, for example).

The circuit breaker includes a power supply circuit that supplies power to a control circuit that controls a main circuit to a conduction state via a mechanical switch and a semiconductor switch. However, in a case where it takes time from receiving a conduction instruction until a start-up of the power supply circuit in the related art, a start of the operation of the control circuit, such as a current detection or the like, may be delayed.

### SUMMARY

Accordingly, it is an object in one aspect of the embodiments to provide a circuit breaker capable of advancing a start of operation of a control circuit.

According to one aspect of the embodiments, a circuit breaker includes a main circuit; a mechanical switch configured to switch the main circuit between a conduction state and an interruption state; a semiconductor device coupled in series on a downstream side of the mechanical switch and configured to switch the main circuit between the conduction state and the interruption state; a sensor configured to output a signal according to a current flowing through the main circuit; a control circuit configured to detect the current flowing through the main circuit based on an output signal of the sensor; and a power supply circuit coupled to an upstream side of the mechanical switch via a first switch and configured to supply power to the control circuit when the first switch is turned on.

The object and advantages of the embodiments will be realized and attained by means of the elements and combinations particularly pointed out in the claims.

It is to be understood that both the foregoing general description and the following detailed description are exemplary and explanatory and not restrictive of the invention, as claimed.

### BRIEF DESCRIPTION OF THE DRAWINGS

FIG. 1 is a diagram illustrating a configuration of an example of a circuit breaker according to a first

embodiment.

FIG. 2 is a timing chart illustrating an operation example of the circuit breaker according to the first embodiment.

FIG. 3 is a diagram illustrating the configuration of an example of the circuit breaker according to a comparative example.

FIG. 4 is a timing chart illustrating an operation example of the circuit breaker according to the comparative example.

FIG. 5 is a diagram illustrating the configuration of a modification of the circuit breaker according to the first embodiment.

FIG. 6 is a diagram illustrating the configuration of an example of the circuit breaker according to a second embodiment.

FIG. 7 is a front view of an example of the circuit breaker.

### DESCRIPTION OF EMBODIMENTS

Hereinafter, embodiments of the present disclosure will be described with reference to the accompanying drawings.

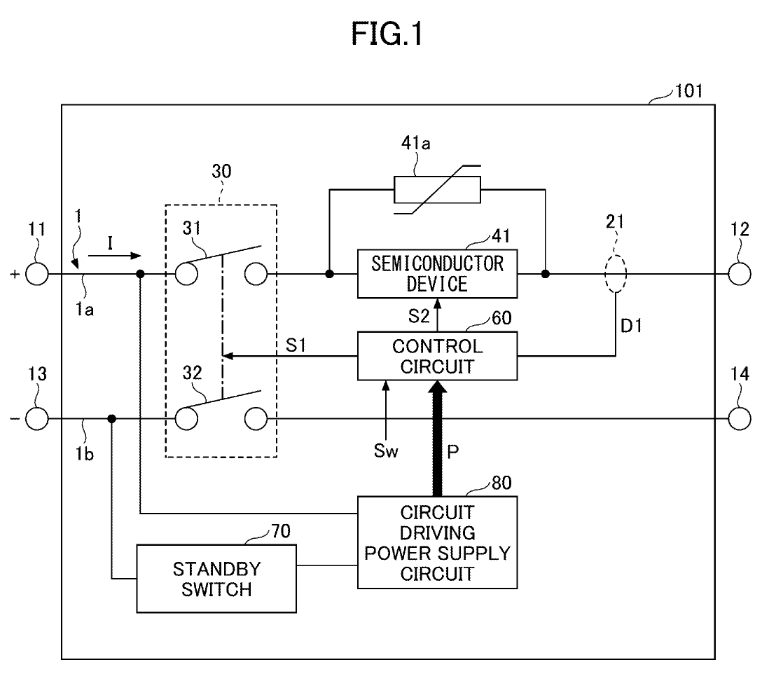

FIG. 1 is a diagram illustrating a configuration of an example of a circuit breaker according to a first embodiment. A circuit breaker 101 illustrated in FIG. 1 is a circuit breaker for wiring protection that interrupts a current I flowing through a main circuit 1 by a mechanical switch 30 and a semiconductor device 41 when the current I exceeds a current (set current) set in the circuit breaker 101. The circuit breaker 101 interrupts the flow of the current I in the main circuit 1 by interrupting the current I exceeding the set current by the mechanical switch 30 and the semiconductor device 41. As a result, a circuit (not illustrated) connected to a downstream side of the circuit breaker 101 is protected from the current I exceeding the set current.

The current I exceeding the set current may be referred to as an overcurrent, for example. The overcurrent may be an overload current flowing through the circuit breaker 101 in an overload state, or may be a short-circuit current generated by a short circuit of a circuit caused by a failure, miswiring, or the like (for example, a short circuit of a circuit (not illustrated) connected on the downstream side of the circuit breaker 101).

The circuit breaker 101 is a DC circuit breaker connected to a DC system. The circuit breaker 101 includes terminals 11, 12, 13, and 14, the main circuit 1, the mechanical switch 30, the semiconductor device 41, a varistor 41a, a sensor 21, a control circuit 60, a standby switch 70, and a power supply circuit 80.

The terminals 11 and 13 are input terminals connected to the DC system. The terminal 11 is a positive electrode input terminal connected to a positive electrode wiring through which a DC current from the DC system flows. The terminal 13 is a negative electrode input terminal connected to a negative electrode wiring, such as a ground wiring or the like, of the DC system.

The terminals 12 and 14 are output terminals to which a DC circuit including a DC load is connected. The terminal 12 is a positive electrode output terminal connected to a positive electrode side of the DC circuit. The terminal 14 is a negative electrode output terminal connected to a negative electrode side of the DC circuit.

The main circuit 1 is a conductive path through which the current I supplied from the DC system flows. In this example, the main circuit 1 includes, as a plurality of conductive paths, a first conductive path 1a connecting the terminals 11 and 12 and a second conductive path 1b connecting the terminals 13 and 14.

The mechanical switch 30 switches the main circuit 1 between a conduction state and an interruption state according to a first switching signal S1 from the control circuit 60. The mechanical switch 30 is provided in the main circuit 1 so as to be able to switch the main circuit 1 between the conduction state and the interruption state. The mechanical switch 30 has a mechanical contact through which the current I flows. Examples of the mechanical switch 30 include a relay, an electromagnetic contactor, or the like.

In this example, the mechanical switch 30 includes, as the plurality of mechanical contacts, a first mechanical contact 31 provided in the first conductive path 1a between the terminal 11 and the semiconductor device 41, and a second mechanical contact 32 provided in the second conductive path 1b between the terminal 13 and the terminal 14. The first mechanical contact 31 switches the first conductive path 1a between a conduction state and an interruption state according to the first switching signal S1 from the control circuit 60. The second mechanical contact 32 switches the second conductive path 1b between a conduction state and an interruption state according to the first switching signal S1 from the control circuit 60.

The semiconductor device 41 switches the main circuit 1 between the conduction state and the interruption state according to a second switching signal S2 from the control circuit 60. The semiconductor device 41 is a semiconductor switch that is provided in the main circuit 1 and switches between interrupting and conducting the current I flowing through the main circuit 1. The semiconductor device 41 is provided in the first conductive path 1a of the main circuit 1 so as to be able to switch the main circuit 1 between the conduction state and the interruption state. The semiconductor device 41 is connected in series on a downstream side of the mechanical switch 30, and in this example, the semiconductor device 41 is connected in series on a downstream side of the first mechanical contact 31. The semiconductor device 41 is provided in the first conductive path 1a between the first mechanical contact 31 and the terminal 12.

The semiconductor device 41 is an insulated gate bipolar transistor (IGBT), a metal oxide semiconductor field effect transistor (MOSFET), a high electron mobility transistor (HEMT), or the like, for example. The semiconductor device 41 may be formed of silicon (Si) as a main material. The semiconductor device 41 may be formed of a wide bandgap semiconductor material as the main material. Examples of the wide bandgap semiconductor material include silicon carbide (SiC), gallium nitride (GaN), gallium oxide (Ga₂O₃), and carbon or diamond (C), or the like.

The varistor 41a is an example of a circuit, connected in parallel to the semiconductor device 41, and configured to protect the semiconductor device 41 from an overcurrent, such as an inrush current or the like. The overcurrent that is generated in the first conductive path 1a when the mechanical switch 30 switches from an off state to an on state attenuates by flowing to the varistor 41a that is connected in parallel to the semiconductor device 41 that is in an off state. The circuit for protecting the semiconductor device 41 from the overcurrent may be a circuit other than the varistor 41a.

The sensor 21 is a current sensor configured to output a signal D1 according to the current I flowing through the main circuit 1. Examples of the sensor 21 include a magnetic field-based current sensor (or magnetic current sensor) or the like.

The control circuit 60 detects the current I flowing through the main circuit 1, based on the signal D1 output from the sensor 21. The control circuit 60 compares a magnitude of the detected current I with a predetermined set current. When the magnitude of the detected current I exceeds the predetermined set current, the control circuit 60 switches the mechanical switch 30 and the semiconductor device 41 from the on state to the off state to interrupt the main circuit 1. The control circuit 60 may display the magnitude of the detected current I on a predetermined display device to enable a user to visually recognize the magnitude of the detected current I. The control circuit 60 may display an operation state of the circuit breaker 101 to enable the user to visually recognize the operation state of the circuit breaker 101.

The power supply circuit 80 is connected to an upstream side of the mechanical switch 30 via the standby switch 70, and supplies a power P to the control circuit 60 when the standby switch 70 is turned on. Accordingly, when the standby switch 70 is turned on, the power supply to the power supply circuit 80 and the control circuit 60 is started before the mechanical switch 30 is turned on, and thus, the power supply circuit 80 and the control circuit 60 are activated in advance before the mechanical switch 30 is turned on. For this reason, when the current I starts to flow through the main circuit 1 by turning on the mechanical switch 30, the control circuit 60 can quickly detect the current I based on the output signal of the sensor 21. Because the control circuit 60 can quickly detect the current I, if the magnitude of the detected current I exceeds the set current, the main circuit 1 can be quickly interrupted by switching the mechanical switch 30 and the semiconductor device 41 from the on state to the off state.

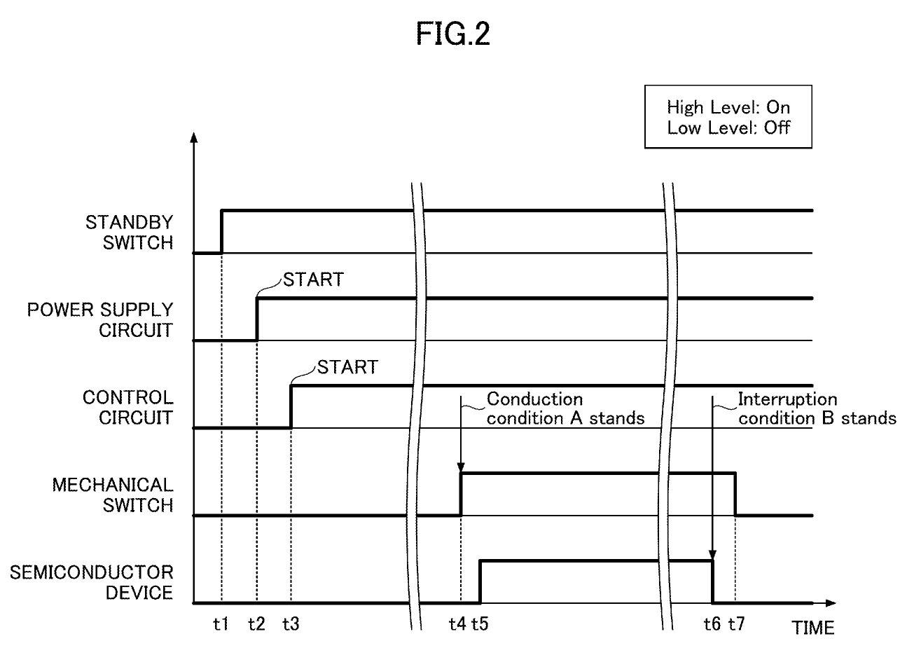

FIG. 2 is a timing chart illustrating an operation example of the circuit breaker according to the first embodiment. The operation illustrated in FIG. 2 will be described with reference to FIG. 1.

When the standby switch 70 is switched from the off state to the on state at a time t1, the power supply from the upstream side of the mechanical switch 30 to the power supply circuit 80 starts, and thus, the power supply circuit 80 is activated at a time t2. After the power supply circuit 80 is activated, the control circuit 60 is activated at a time t3 by the power P supplied from the power supply circuit 80. Accordingly, the power supply circuit 80 and the control circuit 60 are activated in advance before the mechanical switch 30 is turned on.

In a case where a predetermined conduction condition A is satisfied in a state in which the power P is supplied from the power supply circuit 80 to the control circuit 60 by turning on the standby switch 70, the control circuit 60 controls the main circuit 1 to the conduction state via the mechanical switch 30 and the semiconductor device 41. In this example, the control circuit 60 controls the main circuit 1 to the conduction state by causing the mechanical switch 30 to operate at a time t4 and then causing the semiconductor device 41 to operate at a time t5.

When the current I starts to flow through the main circuit 1 by switching the mechanical switch 30 and the semiconductor device 41 from the off state to the on state, the control circuit 60 can quickly detect the current I based on the output signal of the sensor 21. Because the control circuit 60 can quickly detect the current I, the control circuit 60 switches the mechanical switch 30 and the semiconductor device 41 from the on state to the off state in a case where a predetermined interruption condition B is satisfied, such as when the magnitude of the detected current I exceeds the set current. Accordingly, it is possible to quickly interrupt the main circuit 1. In this example, the control circuit 60 operates the semiconductor device 41 at a time t6 before operating the mechanical switch 30 at a time t7, to interrupt the main circuit 1.

As described above, in the circuit breaker 101 according to the first embodiment, the power supply circuit 80 is connected to the upstream side of the mechanical switch 30 via the standby switch 70, and supplies the power to the control circuit 60 when the standby switch 70 is turned on. Hence, it is possible to complete the start-up of the power supply circuit 80 and the activation of the control circuit 60 before the current I starts to flow through the main circuit 1, and to advance the start of the operations of the control circuit 60, such as the detection of the current I flowing through the main circuit 1, the interruption of the current I, or the like.

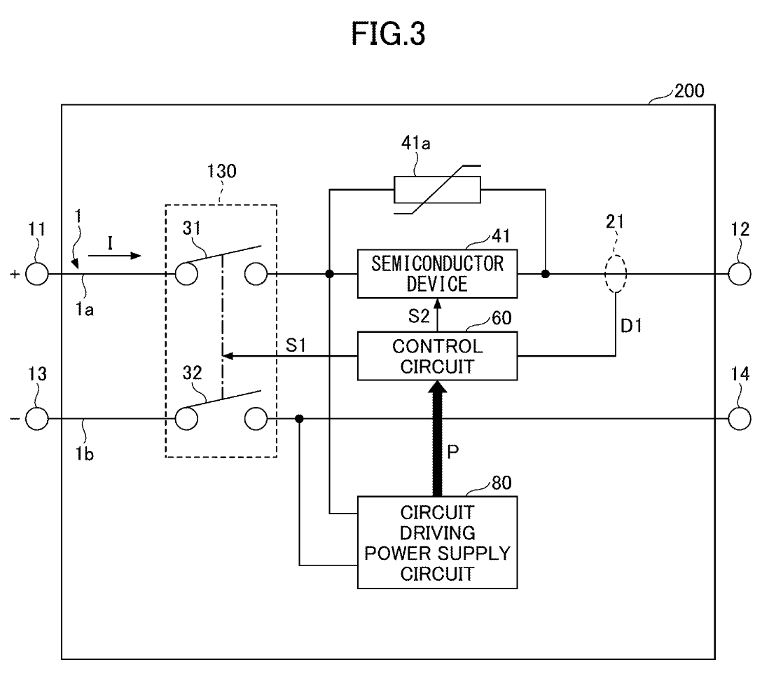

In contrast, in a circuit breaker 200 illustrated in FIG. 3, the power supply circuit 80 is connected to a downstream side of a mechanical manual switch 130. FIG. 3 is a diagram illustrating an example of the configuration of a circuit breaker according to a comparative embodiment.

In the circuit breaker 200 illustrated in FIG. 3, the power supply circuit 80 is connected to the downstream side of the manual switch 130, and supplies the power P to the control circuit 60 when the manual switch 130 is turned on.

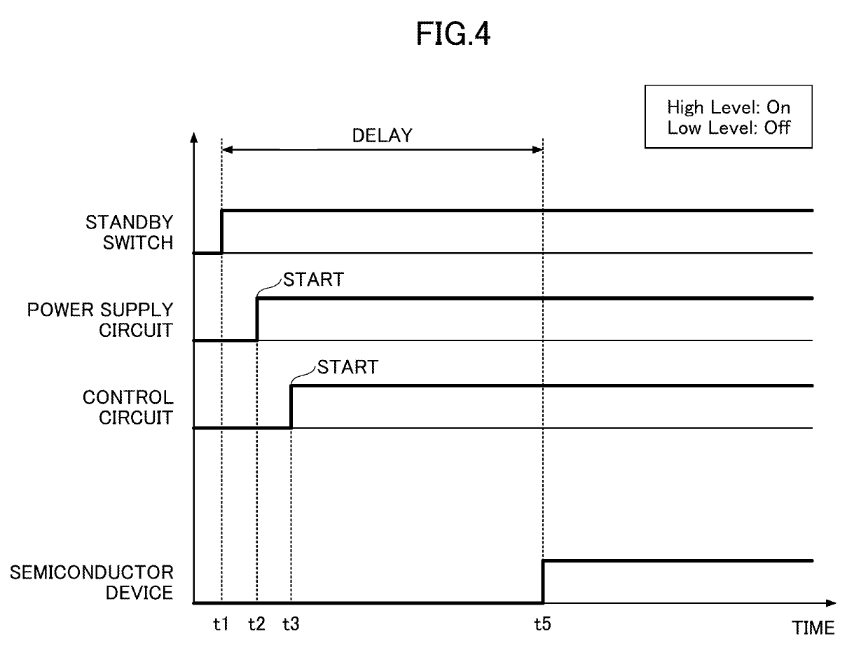

FIG. 4 is a timing chart illustrating an operation example of the circuit breaker according to the comparative embodiment. The operation illustrated in FIG. 4 will be described with reference to FIG. 3.

When the manual switch 130 is switched from an off state to an on state at a time t1, the power supply circuit 80 is activated at a time t2 because the power supply from the downstream side of the manual switch 130 to the power supply circuit 80 is started. After the power supply circuit 80 is activated, the control circuit 60 is activated at a time t3 by the power P supplied from the power supply circuit 80. That is, the power supply circuit 80 and the control circuit 60 are activated after the manual switch 130 is turned on. After the control circuit 60 is activated, the control circuit 60 switches the semiconductor device 41 from the off state to the on state at a time t5. As a result, the current I flows through the semiconductor device 41.

However, in the case of the circuit breaker 200 according to the comparative example, the current I starts to flow through the varistor 41a when the manual switch 130 is turned on. Alternatively, in a case where the semiconductor device 41 is in the ON state and fails, the current I starts to flow through the semiconductor device 41 that failed in the ON state when the manual switch 130 is turned on. Because it takes time from a time when the manual switch 130 is turned on to a time of the start-up of the power supply circuit 80, the control circuit 60 is activated with a delay from a time when the main circuit 1 assumes the conduction state. When the control circuit 60 is activated with a delay from the time when the main circuit 1 assumes the conduction state, there is a possibility that the detection of the current I flowing through the main circuit 1 will become delayed or the interruption of the overcurrent, such as the short-circuit current or the like flowing through the main circuit 1 will become delayed.

In contrast, as described above, the circuit breaker 101 according to the first embodiment can complete the start-up of the power supply circuit 80 and the activation of the control circuit 60 before the current I starts to flow through the main circuit 1. For this reason, it is possible to advance the start of the operations of the control circuit 60, such as the detection of the current I flowing through the main circuit 1, the interruption of the current I, or the like.

In FIG. 1, the power supply circuit 80 generates a DC power P to be supplied to the control circuit 60 for operating the control circuit 60, based on a power supplied from a DC system located on the upstream side of the mechanical switch 30 via the standby switch 70. The standby switch 70 is electrically connected between the upstream side of the mechanical switch 30 and the power supply circuit 80.

The standby switch 70 is an example of a first switch, and functions as a power switch for switching between a power on and a power off with respect to the circuit breaker 101, for example. The standby switch 70 switches whether or not to supply the power from the upstream side of the mechanical switch 30 to the power supply circuit 80, according to a standby instruction by a user operation or an automatic instruction device. Because the power from the upstream side of the mechanical switch 30 is supplied to the power supply circuit 80 by turning on the standby switch 70, the power supply circuit 80 supplies the DC power P generated based on the power supplied via the standby switch 70 to the control circuit 60. On the other hand, because the power supply from the upstream side of the mechanical switch 30 to the power supply circuit 80 is stopped by turning off the standby switch 70, the power supply circuit 80 stops the supply of the power P to the control circuit 60.

The standby switch 70 has one end thereof connected to the main circuit 1 between the input terminal of the circuit breaker 101 and the mechanical switch 30, and the other end thereof connected to the power supply circuit 80. In this example, the standby switch 70 is electrically connected between the second conductive path 1b and the power supply circuit 80, but the standby switch 70 may be electrically connected between the first conductive path 1a and the power supply circuit 80. The standby switch 70 may be provided between the second conductive path 1b and the power supply circuit 80, and another standby switch 70 may also be provided between the first conductive path 1a and the power supply circuit 80.

The standby switch 70 may be provided outside the circuit breaker 101, as long as the standby switch 70 is connected to the upstream side of the mechanical switch 30, and does not need to be a component of the circuit breaker 101.

In a case where the standby switch 70 is turned on and the power P is supplied from the power supply circuit 80 to the control circuit 60, the control circuit 60 controls the main circuit 1 to the conduction state via the mechanical switch 30 and the semiconductor device 41. As described above, when the standby switch 70 is turned on, the power supply circuit 80 and the control circuit 60 are activated in advance before the mechanical switch 30 is turned on. For this reason, in the case where the power P is supplied from the power supply circuit 80 to the control circuit 60 by turning on the standby switch 70, the control circuit 60 can quickly control the main circuit 1 to the conduction state via the mechanical switch 30 and the semiconductor device 41. Because the main circuit 1 is quickly controlled to the conduction state, the control circuit 60 can quickly perform the current detection by the sensor 21, and can quickly control the main circuit 1 to the interruption state based on the current detection result of the sensor 21.

In a case where the predetermined conduction condition A is satisfied in a state in which the power P is supplied from the power supply circuit 80 to the control circuit 60 by turning on the standby switch 70, the control circuit 60 controls the main circuit 1 to the conduction state via the mechanical switch 30 and the semiconductor device 41. Accordingly, when the conduction condition A is satisfied, the control circuit 60 can quickly control the main circuit 1 to the conduction state via the mechanical switch 30 and the semiconductor device 41.

The conduction condition A is satisfied in a case where a predetermined signal Sw is input to the control circuit 60 in a state in which the power P is supplied from the power supply circuit 80 to the control circuit 60 by turning on the standby switch 70. The predetermined signal Sw is a conduction instruction by a user operation or an automatic instruction device, for example. The conduction instruction is a signal for controlling the main circuit 1 to the conduction state.

The case where the conduction condition A is satisfied is not limited to the input of the predetermined signal Sw to the control circuit 60. For example, the control circuit 60 may determine that the predetermined conduction condition A is satisfied in a case where a predetermined time elapses after a power-on reset of the control circuit 60 is released by the input of the power P from the power supply circuit 80.

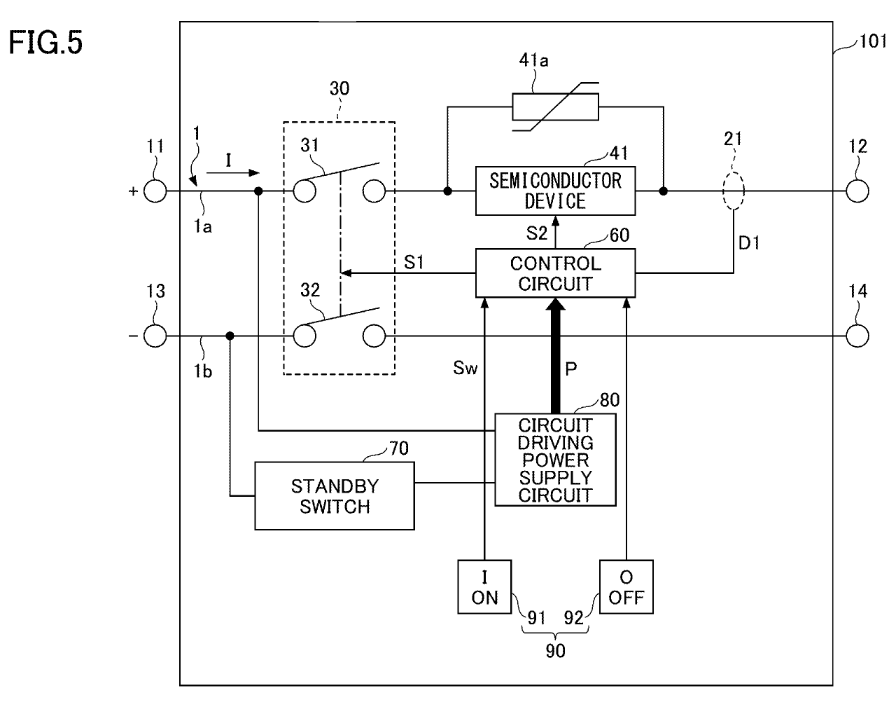

FIG. 5 is a diagram illustrating a modification of the circuit breaker according to the first embodiment. The circuit breaker 101 illustrated in FIG. 5 includes a main switch 90. The main switch 90 includes an on-switch 91 for turning on the main circuit 1 and an off-switch 92 for turning off the main circuit 1. The on-switch 91 is an example of a second switch. The predetermined signal Sw is input to the control circuit 60 by a user operation of the on-switch 91.

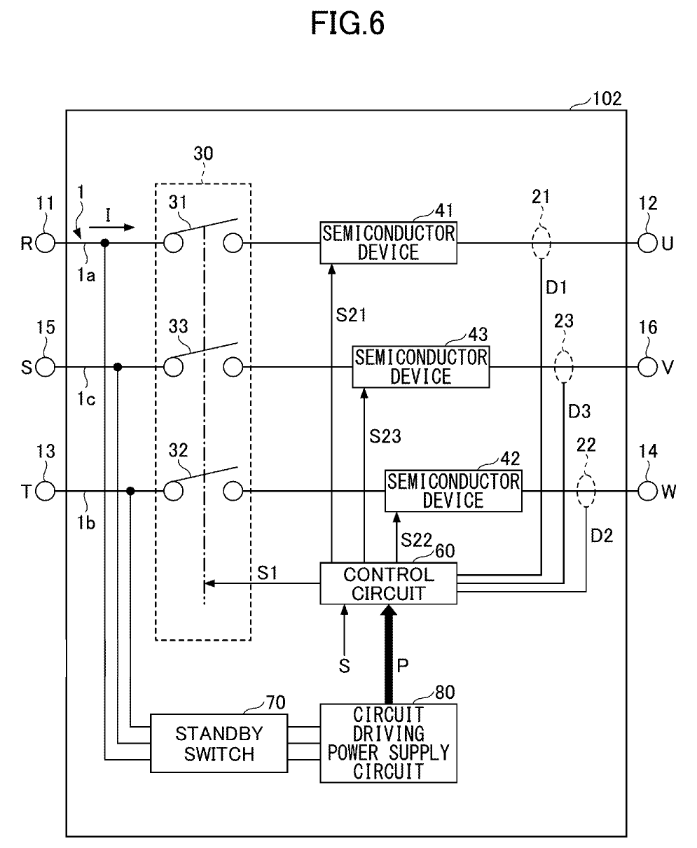

FIG. 6 is a diagram illustrating the configuration of an example of a circuit breaker according to a second embodiment. In the second embodiment, the description of the configuration, operations, and effects that are the same as those of the first embodiment will be omitted or simplified for the sake of convenience, by incorporating the above description.

A circuit breaker 102 illustrated in FIG. 6 is an AC circuit breaker connected to an AC system. The circuit breaker 102 includes terminals 11, 12, 13, 14, 15, and 16, the main circuit 1, the mechanical switch 30, semiconductor devices 41, 42, and 43, sensors 21, 22, and 23, the control circuit 60, the standby switch 70, and the power supply circuit 80.

The terminals 11, 13, and 15 are input terminals connected to the AC system. The terminal 11 is an R-phase input terminal connected to an R-phase wiring through which an AC current from the AC system flows. The terminal 13 is a T-phase input terminal connected to a T-phase wiring through which an AC current from the AC system flows. The terminal 15 is an S-phase input terminal connected to an S-phase wiring through which an AC current from the AC system flows.

The terminals 12, 14, and 16 are output terminals to which a circuit including an AC load is connected. The terminal 12 is a U-phase output terminal connected to a U-phase of the AC load. The terminal 14 is a W-phase output terminal connected to a W-phase of the AC load. The terminal 16 is a V-phase output terminal connected to a V-phase of the AC load.

The main circuit 1 is a conductive path through which a current I supplied from an AC system flows. In this example, the main circuit 1 includes, as the plurality of conductive paths, a first conductive path 1a connecting the terminals 11 and 12, a second conductive path 1b connecting the terminals 13 and 14, and a third conductive path 1c connecting the terminals 15 and 16.

The mechanical switch 30 switches the main circuit 1 between the conduction state and the interruption state according to a first switching signal S1 from the control circuit 60. The mechanical switch 30 includes, as the plurality of mechanical contacts, a first mechanical contact 31 provided in the first conductive path 1a between the terminal 11 and the semiconductor device 41, a second mechanical contact 32 provided in the second conductive path 1b between the terminal 13 and the semiconductor device 42, and a third mechanical contact 33 provided in the third conductive path 1c between the terminal 15 and the semiconductor device 43.

The semiconductor devices 41, 42, and 43 switch the main circuit 1 between the conduction state and the interruption state according to second switching signals S21, S22, and S23 from the control circuit 60, respectively. The semiconductor devices 41, 42, and 43 are semiconductor switches that are provided in the main circuit 1 and interrupt or conduct the current I flowing through the main circuit 1. The semiconductor device 41 is connected in series on a downstream side of the first mechanical contact 31 and switches the first conductive path 1a between the conduction state and the interruption state according to the second switching signal S21. The semiconductor device 42 is connected in series on a downstream side of the second mechanical contact 32, and switches the second conductive path 1b between the conduction state and the interruption state according to the second switching signal S22. The semiconductor device 43 is connected in series on a downstream side of the third mechanical contact 33, and switches the third conductive path 1c between the conduction state and the interruption state according to the second switching signal S23.

The semiconductor devices 41, 42, and 43 may be semiconductor switches, such as the IGBTs or the like described above. A circuit, such as a varistor or the like, may be connected in parallel to each of the semiconductor devices 41, 42, and 43.

The sensors 21, 22, and 23 are current sensors that output signals D1, D2, and D3 according to the current I flowing through the main circuit 1, respectively.

The control circuit 60 detects the current I of each phase flowing through the main circuit 1, based on the signals D1, D2, and D3 output from the sensors 21, 22, and 23, respectively. The control circuit 60 compares the magnitude of the detected current I with a predetermined set current. When the magnitude of the detected current I exceeds the predetermined set current, the control circuit 60 switches the mechanical switch 30 and the semiconductor devices 41, 42, and 43 from the on state to the off state to interrupt the main circuit 1.

The power supply circuit 80 is connected to the upstream side of the mechanical switch 30 via the standby switch 70, and supplies the power P to the control circuit 60 by turning on the standby switch 70. Accordingly, it is possible to complete the start-up of the power supply circuit 80 and the activation of the control circuit 60 before the current I starts to flow through the main circuit 1, and to advance the start of the operations of the control circuit 60, such as the detection of the current I flowing through the main circuit 1, the interruption of the current I, or the like.

Although FIG. 6 illustrates the case of a three-phase AC system, in a case of a single-phase AC system, for example, the configuration related to the S-phase (the third conductive path 1c, the semiconductor device 43, the sensor 23, or the like) may be omitted.

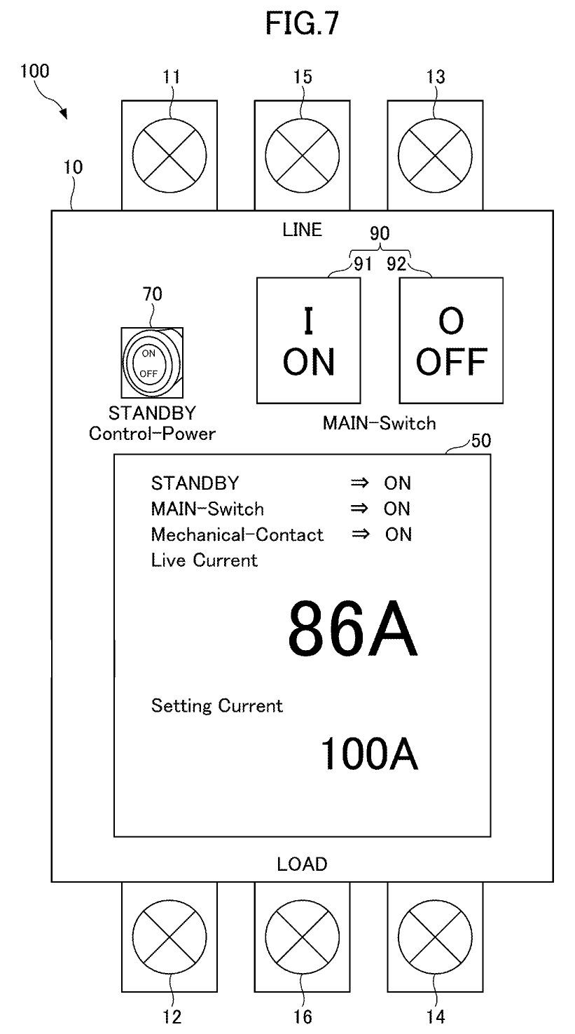

FIG. 7 is a front view of an example of a circuit breaker. A circuit breaker 100 includes a housing 10 and a display device 50. The display device 50 is provided on a surface of the housing 10 so that a display on the display device 50 is visually recognizable by the user. The display device 50 is a display, for example. The display device 50 may display a switch state of the standby switch 70 or may display a switch state of a main switch 90 (an on-switch 91 or an off-switch 92). The display device 50 may display the magnitude of the detected current I or may display the predetermined set current that is set.

The main switch 90 is provided on the surface of the housing 10 so that the main switch 90 is operable by the user. The standby switch 70 is provided on the surface of the housing 10 so that the standby switch 70 is operable by the user.

According to the present disclosure, it is possible to provide a circuit breaker capable of advancing a start of operation of a control circuit.

Although the embodiments are numbered with, for example, “first,” or “second,” the ordinal numbers do not imply priorities of the embodiments. Many other variations and modifications will be apparent to those skilled in the art.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A circuit breaker comprising:
a main circuit;
a mechanical switch configured to switch the main circuit between a conduction state and an interruption state;
a semiconductor device coupled in series on a downstream side of the mechanical switch and configured to switch the main circuit between the conduction state and the interruption state;
a sensor configured to output a signal according to a current flowing through the main circuit;
a control circuit configured to detect the current flowing through the main circuit based on an output signal of the sensor; and
a power supply circuit coupled to an upstream side of the mechanical switch via a first switch and configured to supply power to the control circuit when the first switch is turned on.

2. The circuit breaker as claimed in claim 1, wherein the control circuit controls the main circuit to the conduction state via the mechanical switch and the semiconductor device in a case where the first switch is turned on and the power is supplied from the power supply circuit to the control circuit.

3. The circuit breaker as claimed in claim 2, wherein the control circuit controls the main circuit to the conduction state via the mechanical switch and the semiconductor device in a case where a predetermined conduction condition is satisfied in a state in which the power is supplied from the power supply circuit to the control circuit by turning on the first switch.

4. The circuit breaker as claimed in claim 3, wherein the predetermined conduction condition is satisfied in a case where a predetermined signal is input to the control circuit in a state in which the power is supplied from the power supply circuit to the control circuit by turning on the first switch.

5. The circuit breaker as claimed in claim 4, further comprising:
a second switch,
wherein the predetermined signal is input to the control circuit in response to an operation of the second switch.

6. The circuit breaker as claimed in claim 5, further comprising:
a display device configured to display a state of the second switch.

7. The circuit breaker as claimed in claim 1, wherein:
the main circuit includes a plurality of conductive paths, and
the first switch is electrically connected between the power supply circuit and at least one conductive path of the plurality of conductive paths.

8. The circuit breaker as claimed in claim 1, further comprising:
a display device configured to display a state of the first switch.

9. The circuit breaker as claimed in claim 2, wherein the control circuit operates the mechanical switch before operating the semiconductor device to control the main circuit to the conduction state in a case where the power is supplied from the power supply circuit to the control circuit when the first switch is turned on.

10. The circuit breaker as claimed in claim 1, wherein the control circuit controls the main circuit to the interruption state via the mechanical switch and the semiconductor device in a case where an overcurrent flowing through the main circuit is detected by the control circuit in a state in which the main circuit is controlled to the conduction state via the mechanical switch and the semiconductor device.

11. The circuit breaker as claimed in claim 10, wherein the control circuit controls the main circuit to the interruption state by operating the semiconductor device before operating the mechanical switch in a case where an overcurrent flowing through the main circuit is detected by the control circuit in a state in which the main circuit is controlled to the conduction state via the mechanical switch and the semiconductor device.
